(19) United States
(12) Patent Application Publication
(10) Pub. No.: US 2014/0357022 A1
(43) Pub. Date: Dec. 4, 2014

(54) A QFN WITH WETTABLE FLANK

(71) Applicant: Cambridge Silicon Radio Limited, Cambridge (GB)

(72) Inventor: Simon Jonathan Stacey, Ely (GB)

(21) Appl. No.: 13/909,971

(22) Filed: Jun. 4, 2013

(51) Int. Cl. H01L 21/56; H01L 23/495; H01L 21/78

(52) U.S. Cl. CPC H01L 21/565; H01L 21/78; H01L 23/495
USPC 438/112; 257/666; 249/187.1

(57) ABSTRACT

Methods of fabricating a QFN with wettable flank are described. In an embodiment, a leadframe is used which comprises regions of reduced thickness dam bar which extend across an edge of a kerf width and the QFN are formed using film assisted molding with a shaped mold chase that comprises raised portions which correspond in shape and position to the one or more regions of reduced thickness in the leadframe. The shaped mold chase prevents mold compound from filling recesses under the regions of reduced thickness of leadframe and once diced, each QFN has an edge structure which comprises a small step, into which solder will wet where there are exposed plated leads.

### BACKGROUND

Quad Flat No Lead (QFN) packages use a leadframe as a substrate onto which one or more integrated circuits (ICs) are attached and subsequently wirebonded to form electrical connections from each IC (or die) to the leads of the leadframe. The leadframe provides leads which are plated on their underside to enable soldering to a PCB and provide electrical connections to the package. Additionally, there may be a large plated area on the underside of the leadframe in the centre of the package under the die for soldering to the PCB which provides mechanical strength, a thermal path and is often used as a ground connection for the package.

Initially the leadframes for many packages are connected together by an additional piece of leadframe known as a ‘dam bar’ or ‘tie bar’. The resultant array of individual QFN packages forms a strip which enables many packages to be processed either at the same time or sequentially without requiring the loading and unloading of small leadframes from equipment each time. Following die attach and wirebonding (and/or potentially other packaging processes such as flip chip attach), the combined leadframe and die assembly is overmolded and a cross-section 100 through an example resulting structure is shown in FIG. 1. A singulation process, such as sawing or punching is then used to separate the individual QFNs.

FIG. 1 shows a cross-section 100 through three identical QFNs 101-103 prior to the singulation process. It will be appreciated that although this example only shows 3 QFNs, the leadframe and die assembly (prior to singulation) will comprise many more QFNs, typically arranged in a 2 dimensional array (e.g. as shown in the second diagram 104 which is an example of a leadframe strip viewed from above). The overall size of the strip, and consequently the number of QFN packages in the array, is set by the size of the mold chase used for the over mold process. Each QFN 101-103 shown in FIG. 1 comprises a die 106 mounted on a leadframe 108. Although the leadframe does not appear to be a continuous structure in the cross-section, it will be appreciated that prior to singulation the leadframe assembly for all the QFNs in the 2D array is a single, intricately shaped, piece of metal with thin fingers of metal extending between QFN devices to form the individual leads (i.e. contacts) for each QFN package. If it is not a pretaped leadframe then the leadframe is attached to a tape at this stage to reduce mold flash. The whole structure is overmolded with mold compound 110 and then the underside of the leadframe is plated 112 before singulation. It is also possible to get leadframes pre-plated (PPF) with a universal finish such as Ni/Pd in which case the post mold plating process is not required. During the singulation process material is removed from between each QFN and this removed material, referred to as the ‘kerf width’ is indicated by the dotted lines 114.

The embodiments described below are not limited to implementations which solve any or all of the disadvantages of known methods of forming a QFN.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Methods of fabricating a QFN with wettable flank are described. In an embodiment, a leadframe is used which comprises regions of reduced thickness dam bar which extend across an edge of a kerf width and the QFN are formed using film assisted molding with a shaped mold chase that comprises raised portions which correspond in shape and position to the one or more regions of reduced thickness in the leadframe. The shaped mold chase prevents mold compound from filling recesses under the regions of reduced thickness of leadframe and once diced, each QFN has an edge structure which comprises a small step, into which solder will wet where there are exposed plated leads.

A first aspect provides a method of forming a plurality of QFN packages, the method comprising: loading a populated leadframe strip into a shaped mold chase; and overmolding the populated leadframe strip using film assisted molding, wherein the leadframe comprises one or more regions of reduced thickness which extend across an edge of a kerf width, and the shaped mold chase comprises raised portions which correspond in shape and position to the one or more regions of reduced thickness in the leadframe.

A second aspect provides a leadframe assembly for use in fabricating a plurality of QFN packages, the leadframe assembly comprising one or more regions of reduced thickness which extend across an edge of a kerf width.

A third aspect provides a shaped mold chase for use in fabricating a plurality of QFN packages using a leadframe assembly comprising one or more regions of reduced thickness which extend across an edge of a kerf width, and wherein the shaped mold chase comprises raised portions which correspond in shape and position to the one or more regions of reduced thickness in the leadframe.

The preferred features may be combined as appropriate, as would be apparent to a skilled person, and may be combined with any of the aspects of the invention.

### BRIEF DESCRIPTION OF THE DRAWINGS

Embodiments of the invention will be described, by way of example, with reference to the following drawings, in which:

FIG. 1 is a schematic diagram showing a cross-section through three identical QFNs prior to the singulation process and a 2D array of QFNs in plan view;

FIG. 2 is a schematic diagram showing a QFN in cross-section and side view;

FIG. 3 shows the QFN of FIG. 2 soldered to a PCB;

FIG. 4 is a flow diagram of an improved method of fabricating a QFN;

FIG. 5 shows various schematic diagrams representing stages in the method of FIG. 4;

FIG. 6 shows schematic diagrams of a 2D array of QFNs and a corresponding shaped mold chase;

FIG. 7 shows the QFN of FIG. 5 soldered to a PCB and a 3D view of the QFN of FIG. 5;

FIG. 8 shows various schematic diagrams representing stages in the method of FIG. 4; and

FIG. 9 shows schematic diagrams of a 2D array of punch QFNs and a corresponding shaped mold chase.

Common reference numerals are used throughout the figures to indicate similar features.

### DETAILED DESCRIPTION

Embodiments of the present invention are described below by way of example only. These examples represent the best ways of putting the invention into practice that are currently known to the Applicant although they are not the only ways in which this could be achieved. The description sets forth the functions of the example and the sequence of steps for constructing and operating the example. However, the same or equivalent functions and sequences may be accomplished by different examples.

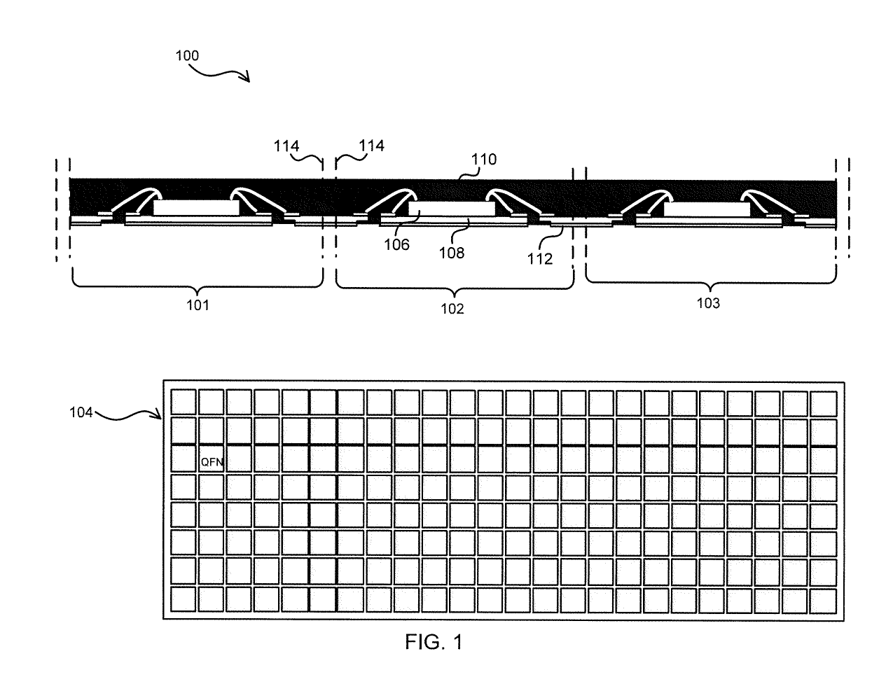

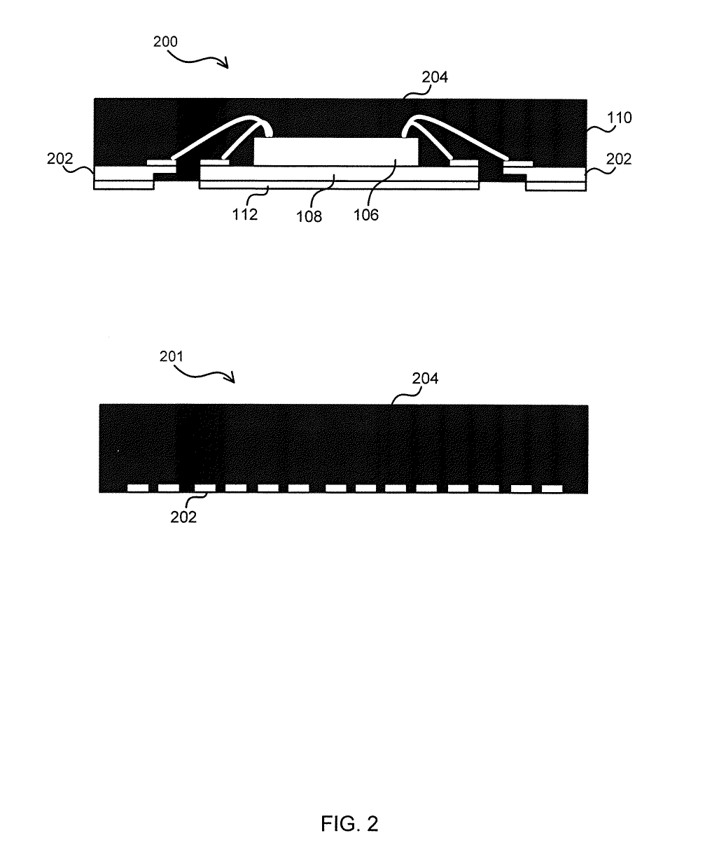

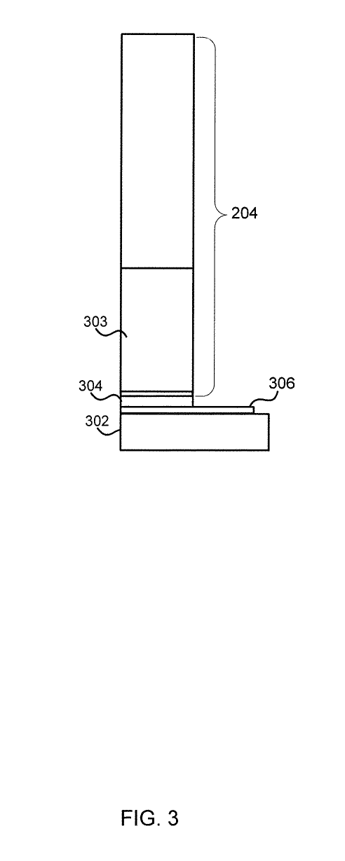

The plated underside 112 of a QFN 101-103, as shown in FIG. 1, provides a wettable surface for the solder when the QFN is soldered onto a PCB. However, as shown in FIG. 2, the singulation process (where the material between dotted lines 114 in FIG. 1 is removed) reveals bare, unplated, leadframe 202 (typically made of copper) at the edges of the package 204. FIG. 2 shows both a cross-section 200 and a side view 201 of the package 204. The side view 201 shows the multiple separate contacts to the QFN 204 each of which may be connected to a different pad on a PCB using solder. Each of these contacts is the end of a lead in the leadframe for the QFN package. The bare leadframe 202 becomes oxidized and as a result the solder does not reliably wet to these edges when solder mounting the package 204 onto a PCB. An example solder fillet under the package 204 is shown in the cross-section 300 in FIG. 3. This cross-section shows an expanded portion of one edge of the package 204, the PCB 302, the contact on the package 303 and the solder fillet 304 between the package 204 and PCB 302. As is shown in FIG. 3, the solder fillet 304 does not extend beyond the edge of the package 204 and therefore cannot easily be visually inspected. Visual inspection cannot therefore be used to determine if there is a good connection between the contact 303 and the pad 306 on the PCB 302.

The inability to visually inspect the solder fillet 304 could lead to reliability problems which may be particularly important for QFNs which are used in applications where reliability is critical, such as for automotive applications. If the solder fillet 304 cannot be inspected, there is no quick and easy check that the solder fillet actually extends to the edge of the package and that there is a good connection to the contacts on the package. In fact, visual inspection cannot determine whether there is any electrical or physical connection at all. Alternatives to visual inspection, such as X-ray, are not practical for large volumes, e.g. it is not feasible to X-ray each soldered QFN on a production line; however visual inspection (which may be automated) can be performed on these large volumes (and may also be used to check other aspects of the production process).

A solution to this problem of the inability to visually inspect solder fillets has been proposed which involves etching a small cavity within the end of a lead (e.g. with the width of about half a lead) and into which the solder can then wet. However, this solution only provides a small wettable flank and is limited to larger pitches of leads (e.g. ≧0.5 mm) as small pitch leads are too small to accommodate the cavity. In addition, the singulation process may result in burring which stops the solder wetting into the tiny cavity unless an additional deburring operation is introduced.

An improved method of fabricating QFN packages is described below which uses Film Assisted Molding (FAM) and provides a QFN which has an edge structure 510 which is different to that shown in FIG. 2 and described above. As a result of the edge structure formed using the improved method, the solder fillet formed when soldering the QFN to a PCB can easily be seen in a visual inspection process. This enables the quality of the solder fillet to be checked and QFNs which do not have a good quality solder fillet to be reworked or rejected, resulting in an increase in the reliability of the soldered QFNs. Furthermore the method may be used for any pitch of leads (or connections) and there is no minimum or maximum pitch to which it is suited.

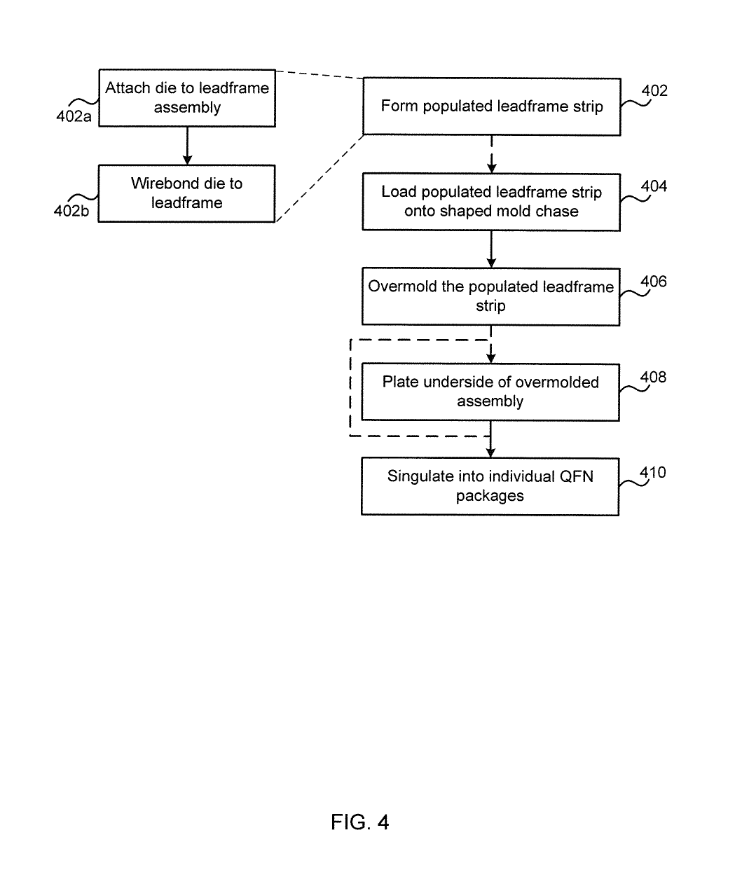

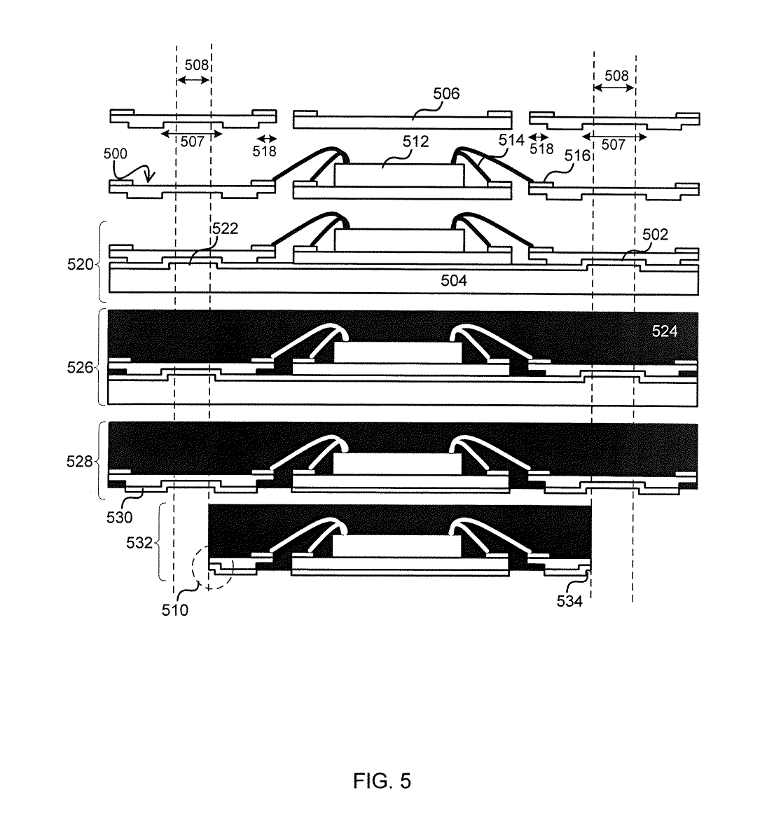

The improved method of fabricating QFN packages can be described with reference to the example flow diagram in FIG. 4 and the schematic diagrams in FIGS. 5-7. The method comprises loading a populated leadframe strip 500 onto a film 502 on a shaped mold chase 504 (block 404) and then overmolding the assembly (block 406) and this is described in more detail below.

It will be appreciated that the populated leadframe strip may be populated with one or more IC per QFN package and the electrical connections between the IC(s) and the leadframe may be formed by wirebonding, soldering or other interconnect techniques.

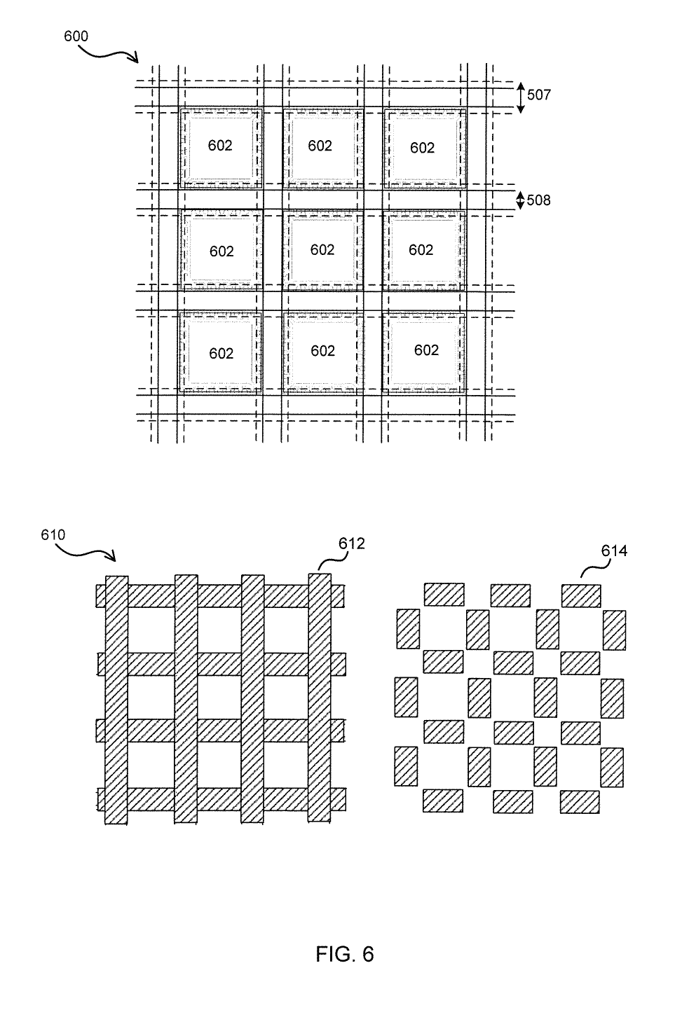

The leadframe 506 which is used in this method comprises one or more regions 507 of reduced thickness dam bar in the vicinity of the kerf width 508. The kerf width 508 is indicated in FIG. 5 by a pair of dotted lines and during singulation, the material between these dotted lines is removed. In the example shown in FIG. 5, the leadframe 506 comprises a thinned region 507 which is slightly wider than the kerf width 508 (e.g. 20-50 μm wider, although this may depend on the width of the kerf and thickness of the leadframe, with large values for wider kerf widths and thicker leadframes). FIG. 5 shows a cross-section through a QFN and it will be appreciated that the region 507 extends around the periphery (i.e. around all four sides) of the QFN and is replicated for each QFN in the 2D array of QFNs which are being processed together from a single leadframe strip as shown in FIG. 6.

The regions of reduced thickness 507 in the leadframe 506 may be formed in any way. For example, the thickness of the leadframe may be reduced in these regions 507 by half-etching the leadframe or by part-sawing of the leadframe; however other techniques may also be used to achieve the same end result of a region having reduced thickness compared to the rest (or the majority of the rest) of the leadframe.

FIG. 6 shows a portion 600 of a 2D array of QFNs 602 which are being processed together (and made from a single leadframe strip) in plan view (i.e. from above or below). Between each QFN is the kerf width 508 (indicated by solid lines) and this material is removed in the singulation process which creates the individual QFNs 602. FIG. 6 also shows the region 507 of thinned leadframe (indicated by dotted lines) between each QFN 602. As can be seen clearly in the plan view, the thinned regions 507 extend beyond the kerf width 508 on both sides. It will be appreciated that although the region must extend beyond the edge of the kerf width 508 on both sides in the middle of the 2D array (i.e. where there are QFN on both sides of the kerf width 508), where there are QFN around the edge of the array and the kerf width 508 separates the QFN from scrap material, it is not necessary for the thinned region 507 to extend beyond the kerf width into the scrap material.

In an example, if the leadframe is around 200 μm thick and the kerf width is around 100 μm, the region of reduced thickness may extend at least 20 μm beyond the edges of the kerf width. This value of 20 μm may also be dependent upon the accuracy of the singulation process, such that if the accuracy of the singulation process is ±5 μm, the region of reduced thickness extends beyond the edges of the target kerf width (i.e. for a perfectly accurate singulation process) to ensure the resultant edge structure 510 of the QFN is achieved even when the singulation process is offset from the intended position. In another example, the kerf width may be 500 μm wide (e.g. again for a leadframe around 200 μm thick), with a tolerance on the singulation process of ±50 μm and in such an example, the region of reduced thickness may extend by at least 65 μm beyond the edges of the target kerf width (of 500 μm).

The populated leadframe 500 which is placed onto the adhesive film 502 in the shaped mold chase 504 (in block 404) may be formed (in block 402) by attaching the die 512 to the leadframe 506 (block 402a) and then forming wirebonds 514 between pads on the die 512 and pads 516 on the leadframe 506 (block 402b). As shown in FIG. 5, the leadframe 506 may comprise additional regions 518 of reduced thickness in addition to the one or more regions 507 in the vicinity of the kerf width 508. In the description herein, any discussion about the dimensions of a region of reduced thickness relate only to those regions 507 in the vicinity of the kerf width 508 and not to the additional regions 518 which have a different purpose. All the regions of reduced thickness 507, 508 may be formed using the same method (e.g. in the same half etch process step) or using different methods.

The shaped mold chase 504 is shaped such that it has raised portions which correspond to the one or more regions 507 of reduced thickness of leadframe 506 in the vicinity of the kerf width 508. The shaped mold chase 504 may alternatively be described as being ridged in that it comprises a pattern of ridges (which may, in many examples, not have the square cross-section as shown in FIG. 5) which correspond to the regions 507 of reduced thickness as is shown in FIG. 6. FIG. 6 shows a portion 610 of the shaped mold chase 504 in plan view. The raised portions (or ridges) are shown as shaded regions 612 in FIG. 6 and it can be seen by comparing the two schematic diagrams in FIG. 6 that the raised portions 612 in the portion 610 of the shaped mold chase shown correspond to the regions 507 of reduced thickness of leadframe in the portion 600 of the 2D array of QFNs. Alternative mold chase constructions may be designed to serve the same purpose, for example, the raised regions 612 may only extend to cover all leads and not extend into the corner of the packages where no leads reside, as illustrated by the raised regions 614.

It will be appreciated that the width of the ridges will not exactly correspond to the width of the thinned regions 507 as there will be a reduction in the width of the ridges to allow for the thickness of the film 502. The thickness and compliance of the adhesive protection film 502 is selected to provide protection to all solderable surfaces of the leadframe, including the thinned regions 507, whilst allowing for the leadframe and mold chase manufacturing tolerances.

The effect of the raised portions on the shaped mold chase 504 is to protect the regions 507 of reduced thickness from the mold compound when the populated leadframe 500 is overmolded (in block 406). As can be seen in the third diagram 520 in FIG. 5, when the populated leadframe 500 is loaded onto the adhesive film 502 on the shaped mold chase 504 (in block 404), the film 502 and the raised portions 522 are forced into the recesses underneath the thinned regions 507 of the leadframe 506 during the lamination process. The raised portions 522 and film 502 therefore prevent any ingress of mold compound 524 into the recesses during overmolding, and the end result is shown in the fourth diagram 526 in FIG. 5.

Following overmolding (in block 406), the overmolded assembly is removed from the mold chase and the adhesive film 502 is delaminated from the leadframe. The underside may be plated (block 408) as shown in the fifth diagram 528 in FIG. 5 but this method equally applies to pre-plated leadframes where the plating process (block 408) is omitted (as indicated by the dotted arrow). As can be seen in this diagram, because there is no mold compound in the recess under the region 507 of reduced thickness of the leadframe, the underside of the QFN package is not flat in the vicinity of the kerf width 508 and instead the topology of the underside of the leadframe 506 is exposed. The plating process (block 408) covers this topology with a thin layer of material 530 (e.g. tin) which as described above is selected such that it provides a wettable layer for the solder. A singulation process such as sawing or punching may then be used to separate the individual QFN packages 532 (block 410).

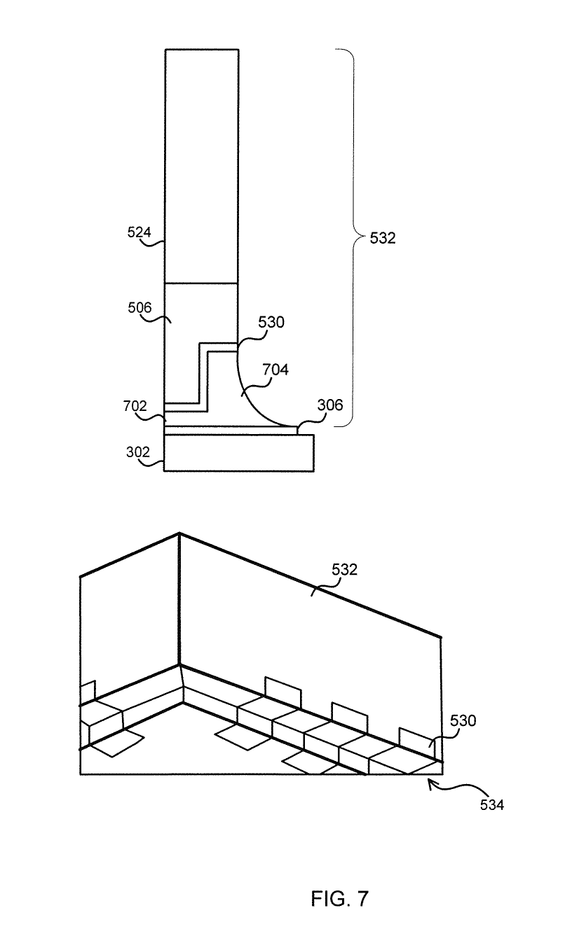

Unlike the QFN package 204 shown in FIG. 2, the QFN package 532 produced using the method described above does not have a planar side wall but instead has an edge structure 510 which includes a step (or notch) 534 at the bottom corner where the QFN package will be soldered onto a PCB. This step 534 extends all around the periphery of the QFN at the bottom face (i.e. the face which will be soldered to a PCB). This step 534 in the leadframe 506 is covered by the plating material 530 where there are exposed leads (or contacts) such that the solder used to mount the QFN onto a PCB wets into the plated step 534 in the lead as shown in FIG. 7.

FIG. 7 shows a cross-section through the edge of a QFN package 532 soldered onto a PCB 302. As can be seen clearly in this expanded view, there is a step 534 in the lead at the bottom corner covered in the plating material 530 and the solder 702 wets into this step 534 to form a shaped fillet 704 which extends beyond the edge of the QFN package 532 and so can be seen in visual inspection. In the example shown in FIG. 7, the solder fillet 704 extends out to the edge of the pad 306 on the PCB 302 to which the QFN is soldered.

FIG. 7 also shows a 3D view of a QFN package 532 before it is soldered. It can clearly be seen from this diagram that the step 534 extends all the way around the bottom edge of the QFN package 532; however there are individual areas of plated material 530 corresponding to each connection on the QFN. When soldering the QFN onto a PCB an individual solder fillet (such as fillet 704) forms under each area of plated material 530 and as a result of the step 534, the fillets are shaped such that each fillet can be inspected by visual inspection. When inspecting a QFN package 532 soldered onto a PCB 302, if a solder fillet is not visible in a position where a solder connection is required/expected (e.g. where there is a pad 306 on the PCB), the package may fail the inspection and be either rejected or submitted for rework.

It will be appreciated that although FIG. 5 and the description above refers to a QFN comprising a single die, in other examples, the QFN may comprise more than one die and/or other discrete components which may be attached when forming the leadframe and die assembly (in block 402).

It will be appreciated that the step 534 shown in FIG. 7 may be modified depending on the patterning of the leadframe and the corresponding mold chase profile employed, for example, the chase raised regions 614 would not provide a step in the molding at the corners of the QFN.

Furthermore, although the above description describes the populated leadframe being placed on an adhesive film on the shaped mold chase, in other examples, the leadframe assembly may be provided (e.g. by the manufacturer) pre-taped, i.e. already mounted on the adhesive film. In such an example, the die attach process is performed whilst the leadframe assembly is mounted on the film and then the leadframe and die assembly on the film is placed onto the shaped mold chase (in block 404).

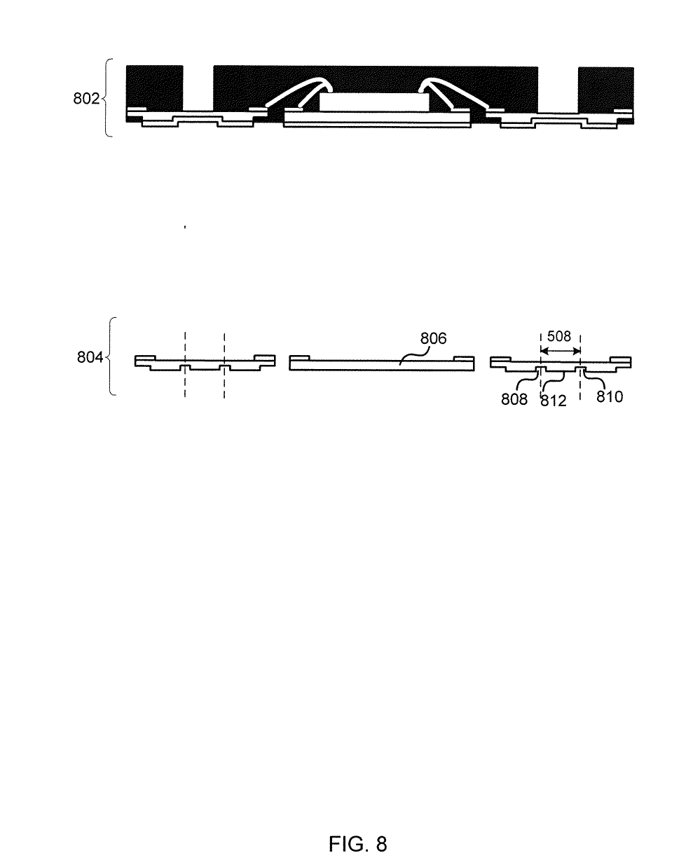

FIGS. 5 and 6 show a single thinned region 507 of leadframe (a thinned region of the dam bar) around each QFN which results in the step structure 534. This structure may be particularly suited to QFNs which are separated (in block 410) by sawing; however it may also be used for other singulation methods (e.g. punching, laser cutting, etc).

Where punching is used (and also for some other singulation techniques), a shaped upper mold chase may be used in order that the mold compound does not extend into the kerf width. This makes the punching process much easier; however, as there is now no mold compound in the kerf width, the overall structure (prior to singulation), as shown in the first diagram 802 in FIG. 8 is more fragile than the alternative structure shown in the fourth diagram 528 in FIG. 5. In order to make this structure more robust (which may improve the punching operation), an alternative design of leadframe 806 may be used, as shown in the second diagram 804 in FIG. 8.

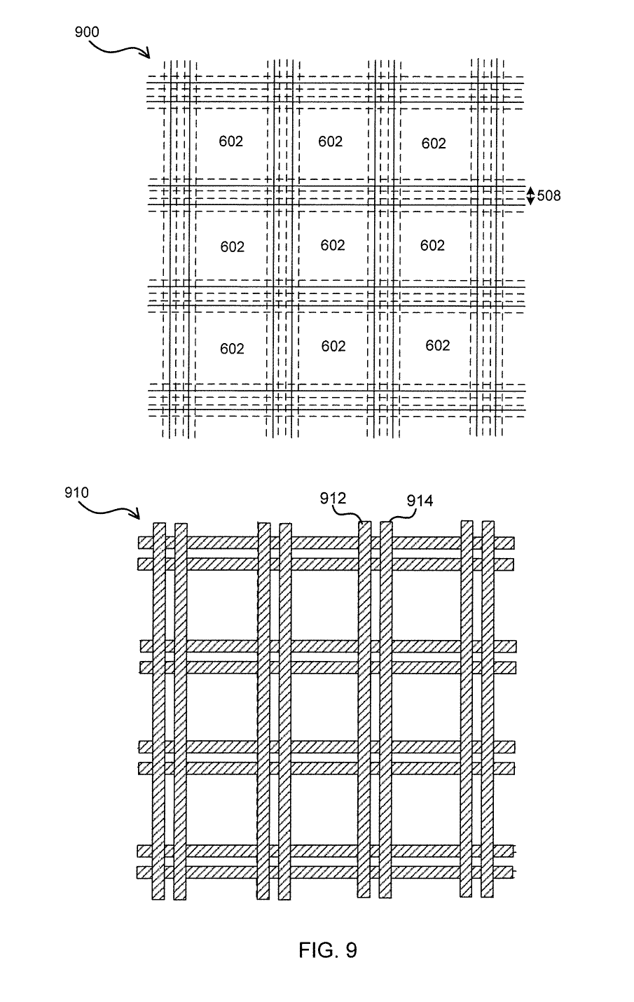

The second diagram 804 in FIG. 8 shows a cross-section through a leadframe 806 which comprises two regions 808, 810 of reduced thickness dam bar in the vicinity of the kerf width 508 separated by a region 812 of full thickness of leadframe. As can be seen from the plan view 900 in FIG. 9 and from diagram 804, each region 808, 810 of reduced thickness of leadframe straddles an edge of the kerf width 507 and there is a region 812 of full thickness of leadframe at the centre of the kerf width. This increases the robustness of the overmolded structure prior to singulation.

It will be appreciated that these leadframe designs are given by way of example only and alternative designs could be implemented such as not extending the reduced thickness regions 507, 808 and 810 into the dam bar intersections, i.e. package corners, to improve leadframe rigidity.

Any suitable dimensions of regions 808,810 may be used which results in the structure of a QFN (and edge structure 510) as shown in the final diagram in FIG. 5. In an example, each region 808, 810 may straddle the edge of the kerf width and extend beyond the kerf width and into the QFN by at least 20 μm. However, as described above, this dimension may depend on many factors, such as the thickness of the leadframe and/or kerf width and the accuracy of the singulation process. As a result, the dimension may be significantly larger (e.g. at least 50 μm).

Where a leadframe with two regions 808, 810 of reduced thickness in the vicinity of the kerf width 507 is used, a corresponding shaped lower mold chase 910 is used which comprises pairs of ridges 912, 914 instead of the single ridges 612 shown in FIG. 6. These pairs of ridges 912, 914 correspond to the regions 808, 810 of reduced thickness and protect the regions from ingress of mold compound during overmolding (in block 406). As described above with reference to FIG. 6, at the edges of the 2D array, there is no need to form the stepped edge structure 510 in scrap material and therefore there may not be the outer ridge at the periphery of the shaped mold chase (e.g. at the periphery of the 2D array of QFN packages).

Where two regions 808, 810 of reduced thickness are used, the method used is unchanged (the shaped mold chase still corresponds to the regions of reduced thickness in the leadframe which are in the vicinity of the kerf width) and the resultant structure of the QFN is the same (e.g. the same as package 532 in FIGS. 5 and 7). This means that the solder fillet shape is the same, leading to the same ability to inspect and check the solder fillets.

The methods described above do not require any additional process steps. The method is improved through use of a new design of leadframe and a correspondingly shaped lower mold chase.

It will be appreciated that although the diagrams show a leadframe and mold chase with sharp, right angle corners, there may in reality be rounded (e.g. as a result of processing artifacts), for example, half-etching of the leadframe results in rounded corners. Rounded corners help to ensure good adhesion to the film 502 and reduced mold flash (i.e. ingress of mold compound) under the regions of reduced thickness.

Although the reduced thickness regions 507, 808, 810 are shown as being approximately half the thickness of the leadframe, in other examples the thinned regions may be thicker (e.g. 75% of the full thickness) or thinner (e.g. 30% of the full thickness).

As described above, the improved method leads to improved inspection to guarantee reliability of the QFN package and the components in which they are used. Additionally, the improved method can be used on any pitch of leads (e.g. including leads having a pitch of 0.35 mm or less) and does not require any additional process steps or result in additional process cost or cycle time.

As described above, the improved methods described above are applicable to both non-PPF and PPF leadframes. Where the methods are used with PPF leadframes, the plating step shown in FIG. 4 (block 408) is omitted and, as for non-PPF leadframes, the raised portions of the shaped mold chase serve to protect the thinned regions of dam bar from being underfilled by mold compound.

Any range or device value given herein may be extended or altered without losing the effect sought, as will be apparent to the skilled person.

It will be understood that the benefits and advantages described above may relate to one embodiment or may relate to several embodiments. The embodiments are not limited to those that solve any or all of the stated problems or those that have any or all of the stated benefits and advantages.

Any reference to ‘an’ item refers to one or more of those items. The term ‘comprising’ is used herein to mean including the method blocks or elements identified, but that such blocks or elements do not comprise an exclusive list and a method or apparatus may contain additional blocks or elements.

The term ‘subset’ is used herein to refer to a proper subset, i.e. a subset of elements does not comprise all the elements in the set.

The steps of the methods described herein may be carried out in any suitable order, or simultaneously where appropriate. Additionally, individual blocks may be deleted from any of the methods without departing from the spirit and scope of the subject matter described herein. Aspects of any of the examples described above may be combined with aspects of any of the other examples described to form further examples without losing the effect sought.

It will be understood that the above description of a preferred embodiment is given by way of example only and that various modifications may be made by those skilled in the art. Although various embodiments have been described above with a certain degree of particularity, or with reference to one or more individual embodiments, those skilled in the art could make numerous alterations to the disclosed embodiments without departing from the spirit or scope of this invention.

1. A method of forming a plurality of QFN packages, the method comprising:
loading a populated leadframe strip into a shaped mold chase; and
overmolding the populated leadframe strip using film assisted molding,
wherein the leadframe comprises one or more regions of reduced thickness which extend across an edge of a kerf width, and
the shaped mold chase comprises raised portions which correspond in shape and position to the one or more regions of reduced thickness in the leadframe.

2. A method according to claim 1, wherein the populated leadframe strip is attached to an adhesive film and wherein loading a populated leadframe strip into a shaped mold chase comprises forcing the adhesive film into recesses under the one or more regions of reduced thickness.

3. A method according to claim 1, wherein the raised portions of the shaped mold chase prevent mold compound from filling recesses under the one or more regions of reduced thickness during the overmolding.

4. A method according to claim 1, wherein each kerf width corresponds to a strip of material removed between adjacent QFN packages when separating the QFN packages and each kerf width has two parallel edges.

5. A method according to claim 4, wherein the one or more regions of reduced thickness comprises one region of reduced thickness corresponding to each kerf width and which extends beyond each edge of the kerf width.

6. A method according to claim 5, wherein each kerf width comprises a saw street and the QFN packages are arranged to be separated by sawing.

7. A method according to claim 4, wherein the one or more regions of reduced thickness comprises a pair of parallel regions of reduced thickness corresponding to each kerf width, each region straddling one of the edges of the kerf width.

8. A method according to claim 7, wherein the QFN packages are arranged to be separated using a punch process.

9. A method according to claim 1, wherein the shaped mold chase comprises a plurality of ridges, each ridge corresponding in shape and position to a region of reduced thickness.

10. A method according to claim 1, further comprising:
singulating the overmolded populated leadframe strip into individual QFN packages.

11. A method according to claim 1, further comprising:
forming the populated leadframe strip.

12. A leadframe assembly for use in fabricating a plurality of QFN packages, the leadframe assembly comprising one or more regions of reduced thickness which extend across an edge of a kerf width.

13. A leadframe assembly according to claim 12, wherein each kerf width corresponds to a strip of material removed between adjacent QFN packages when separating the QFN packages and each kerf width has two parallel edges.

14. A leadframe assembly according to claim 13, wherein the one or more regions of reduced thickness comprises one region of reduced thickness corresponding to each kerf width and which extends beyond each edge of the kerf width.

15. A leadframe assembly according to claim 14, wherein each kerf width comprises a saw street and the QFN packages are arranged to be separated by sawing.

16. A leadframe assembly according to claim 13, wherein the one or more regions of reduced thickness comprises a pair of parallel regions of reduced thickness corresponding to each kerf width, each region straddling one of the edges of the kerf width.

17. A leadframe assembly according to claim 16, wherein the QFN packages are arranged to be separated using a punch process.

18. A shaped mold chase for use in fabricating a plurality of QFN packages using a leadframe assembly comprising one or more regions of reduced thickness which extend across an edge of a kerf width, and wherein the shaped mold chase comprises raised portions which correspond in shape and position to the one or more regions of reduced thickness in the leadframe.

19. A shaped mold chase according to claim 18, wherein the shaped mold chase comprises a plurality of ridges, each ridge corresponding in shape and position to a region of reduced thickness.

20. A shaped mold chase according to claim 18, wherein each kerf width corresponds to a strip of material removed between adjacent QFN packages when separating the QFN packages, each kerf width has two parallel edges and each of the one or more regions of reduced thickness extends beyond at least one edge of the kerf width.
